(19) United States
(12) Patent Application Publication
(10) Pub. No.: US 2004/0113605 A1
(43) Pub. Date: Jun. 17, 2004

(54) Test device of A/D converter

(75) Inventor: Kazuhiro Nishimura, Tokyo (JP)

Correspondence Address: BURNS DOANE SWECKER & MATHIS L L P, POST OFFICE BOX 1404, ALEXANDRIA, VA, 22313-1404, US

(73) Assignee: RENESAS TECHNOLOGY CORP.

(21) Appl. No.: 10/731,082

(22) Filed: Dec. 10, 2003

(30) Foreign Application Priority Data
Dec. 17, 2002 (JP) 2002-365650

(51) Int. Cl. G01R 13/02

(52) U.S. Cl. 324/76.82

(57) ABSTRACT

A test device of an A/D converter includes a compare decision circuit for comparing the output code of an A/D converter with a specified digital code representing a bit transition point, and for generating a digital signal corresponding to the difference between the two codes compared. During a period where the output code of the A/D converter is greater than the digital code representing the bit transition point, a switching circuit connects to an integrator circuit one of a positive current source and negative current source, which reduces the integral output, and otherwise the other of the two current sources that increases the integral output. An adder-subtracter circuit superimposes a specified triangular or sawtooth wave signal on the integral output of the integrator circuit, and supplies it to the converter. The test device can automatically measure the bit transition point of the specified digital code at high speed.

### BACKGROUND OF THE INVENTION

1. Field of the Invention

The present invention relates to a test device of an A/D converter for facilitating its-test.

2. Description of Related Art

FIG. 8 is a block diagram showing a principle configuration of a conventional test circuit of an A/D converter (see, Relevant References 1, 2 and 3, for example). The output digital signal 502 of an A/D converter 501 to be measured is supplied to a control circuit 535 to undergo decision. A control signal produced as a decision result is supplied to a variable power supply 536 via a signal path 537. The voltage value supplied to the input terminal 509 of the A/D converter 501 to be measured is fed from the variable power supply 536, the voltage value of which is varied by the control in response to the control signal. The control circuit 535 compares the output digital signal 502 of the A/D converter 501 with a specified digital code. When the output digital signal is greater, the control circuit 535 outputs the control signal for reducing the output voltage of the variable power supply 536. In contrast, when the output digital signal 502 is smaller, the control circuit 535 outputs the control signal for increasing the output voltage. The control circuit 535 stores its input voltage at which the output digital signal 502 finally arrives as a bit transition point corresponding to the digital code. It is common for the conventional test to implement the control circuit 535 and variable power supply 536 by using the functions of a measurement device called tester.

Relevant Reference 1: Japanese patent application laid-open No. 2-145022/1990 (FIG. 1).

Relevant Reference 2: Japanese patent application laid-open No. 56-79965/1981 (FIG. 1).

Relevant Reference 3: Japanese patent application laid-open No. 4-129331/1992 (FIGS. 2 and 3).

These Relevant References 1-3 are incorporated herein by reference.

To measure the bit transition point corresponding to the specified digital code by the conventional test circuit of the A/D converter with the foregoing configuration, it is necessary for a user to iterate the measurement routine of finely adjusting the input voltage with monitoring the digital output signal of the A/D converter, which is tedious and time consuming. In particular, to carry out the measurement at high accuracy, there is a problem of increasing the number of repetitions exponentially.

### SUMMARY OF THE INVENTION

The present invention is implemented to solve the foregoing problem. It is therefore an object of the present invention to provide a high-speed test device of an A/D converter capable of facilitating measurement without the tedious measurement routine by automatically adjusting the input voltage to the A/D converter to the bit transition point which is set by inputting a specified digital code.

According to one aspect of the present invention, there is provided a test device of an A/D converter, which superimposes a triangular wave signal on an input voltage to the A/D converter during measurement of its bit transition point. The test device includes a compare decision circuit that compares the output digital code of the A/D converter with a digital code set for the measurement. The compare decision circuit supplies an integrator circuit with a digital signal as a decision output to control the current supplied to the integrator circuit in response to the duty factor corresponding to the difference between the two digital codes compared. This makes it possible for the test device to automatically adjust the input voltage to the A/D converter to the voltage at the bit transition point. The test device offers an advantage of being able to speed up and facilitate the measurement of the bit transition point.

### BRIEF DESCRIPTION OF THE DRAWINGS

FIG. 1 is a circuit diagram showing a configuration of an embodiment 1 of the test device of an A/D converter in accordance with the present invention;

FIG. 2 is a time chart illustrating the operation of the embodiment 1 in accordance with the present invention;

FIG. 3 is a circuit diagram showing a configuration of an embodiment 2 of the test device of an A/D converter in accordance with the present invention;

FIG. 4 is a time chart illustrating the operation of the embodiment 2 in accordance with the present invention;

FIG. 5 is a circuit diagram showing a configuration of an embodiment 3 of the test device of an A/D converter in accordance with the present invention;

FIG. 6 is a circuit diagram showing a configuration of an embodiment 4 of the test device of an A/D converter in accordance with the present invention;

FIG. 7 is a time chart illustrating the operation of the embodiment 4 in accordance with the present invention; and

FIG. 8 is a circuit diagram illustrating a measurement of a conventional A/D converter.

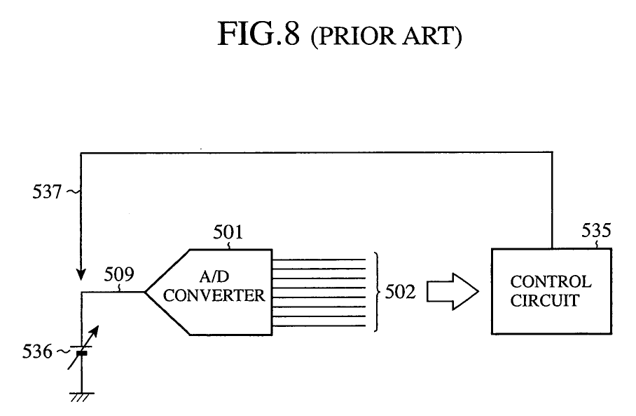

### DETAILED DESCRIPTION OF THE PREFERRED EMBODIMENTS

The invention will now be described with reference to the accompanying drawings.

### EMBODIMENT 1

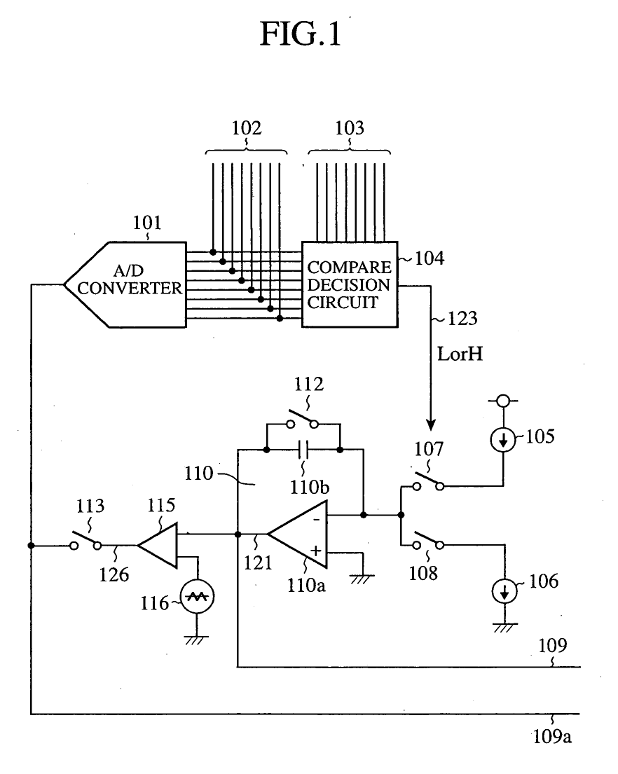

FIG. 1 is a circuit diagram showing a configuration of an embodiment 1 of the test device of an A/D converter in accordance with the present invention. In FIG. 1, an A/D converter 101 to be measured A/D converts an input analog signal, and outputs a digital signal 102 from its output terminal. The digital signal 102 is supplied to a compare decision circuit 104. The compare decision circuit 104 compares the digital signal 102 with a digital code 103 for deciding a bit transition point supplied via an input terminal for measurement. The compare decision circuit 104 outputs a high voltage (referred to as “H” from now on) if the digital code corresponding to the digital signal 102 is smaller than the digital code 103 for deciding the bit transition point. Otherwise (if the digital code of the digital signal 102 is greater), it outputs a low voltage (referred to as “L” from now on).

The circuit arrangement of FIG. 1 includes a positive current source 105 and negative current source 106, the absolute values of the current values of which are substantially equal. In addition, it includes switches 107 and 108 serving as a switching circuit in accordance with the present invention. The switch 107 connects the positive current source 105 to an integrator circuit 110 composed of an operational amplifier 110a and a capacitor 110b, when the output 123 of the compare decision circuit 104 is “L”.

On the other hand, the switch 108 connects the negative current source 106 to the integrator circuit 110, when the output 123 of the compare decision circuit 104 is “H”. The integrator circuit 110 integrates the current fed from the current source 105 or 106, and supplies the integral output voltage 121 to an adder-subtracter circuit 115. The integral output voltage 121 of the integrator circuit lib is output from an output terminal 109 so that its value is measured. A switch 112 connected in parallel with the capacitor 110b of the integrator circuit 110 is provided for resetting the integrator circuit 110. The adder-subtracter circuit 115 superimposes the triangular wave output from a triangular-wave oscillator 116 on the integral output voltage 121 of the integrator circuit 110, and supplies the resultant voltage 126 to the A/D converter 101 via a switch 113. The switch 113 is kept on only during the test of the A/D converter 101 to be measured, and is kept off during the normal operation of a chip incorporating the A/D converter 101 to be measured.

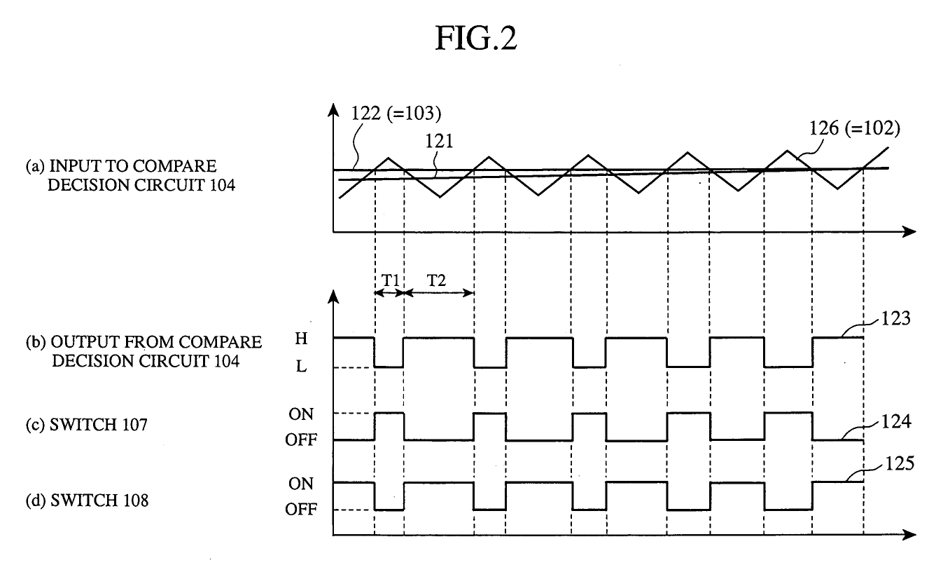

FIG. 2 is a time chart illustrating the operation of the embodiment 1 in accordance with the present invention. In FIG. 2, the reference numeral 122 designates the voltage at the bit transition point corresponding to the specified digital code 103; 121 designates the integral output voltage of the integrator circuit 110; and 126 designates the output voltage of the adder-subtracter circuit 115, the sum of the voltage 121 and the triangular wave superimposed thereon. The reference numeral 123 designates the digital signal as the decision output of the compare decision circuit 104; 124 designates the on/off periods of the switch 107; and 125 designates the on/off periods of the switch 108. The on-time period of the switch 107 represents a time period during which the positive current source 105 is connected to the integrator circuit 110. On the other hand, the on-time period of the switch 108 represents a time period during which the negative current source 106 is connected to the integrator circuit 110.

As easily seen from FIG. 2, the input to the A/D converter 101, that is, the output voltage 126 of the adder-subtracter circuit 115, consists of the integral output voltage 121 of the integrator circuit 110 and the triangular wave superimposed thereon. Thus, the decision output 123 of the compare decision circuit 104 is placed at the “L” level only during the time period T1 in which the output voltage 126 of the adder-subtracter circuit 115 is greater than the voltage 122 at the bit transition point. In contrast, the decision output 123 is placed at the “H” only during the time period T2 in which the output voltage 126 is smaller than the voltage 122. In other words, the decision output 123 becomes a digital signal because of the triangular wave, and its duty factor T2/(T1+T2) varies depending on the voltage 122 at the bit transition point.

When the integral output voltage 121 of the integrator circuit 110 is less than the voltage 122 at the bit transition point, the relation T1<T2 holds because ½<T2/(T1+T2). Accordingly, the negative current source 106 is connected longer than the positive current source 105 to the integrator circuit 110. Thus, the integrator circuit 110 is supplied more with the negative current, thereby increasing the integral output voltage 121 of the integrator circuit 110. On the contrary, although not shown in FIG. 2, when the integral output voltage 121 of the integrator circuit 110 is greater than the voltage 122 at the bit transition point, T1>T2 holds. Accordingly, the positive current source 105 is connected longer than the negative current source 106 to the integrator circuit 110. Thus, the integrator circuit 110 is supplied more with the positive current, thereby decreasing the integral output voltage 121 of the integrator circuit 110.

In this way, the integral output voltage 121 of the integrator circuit 110 approaches the voltage 122 at the bit transition point, resulting in T1=T2. In other words, the control system reaches equilibrium, in which the integral output voltage 121 of the integrator circuit 110 is stable without fluctuations. Therefore picking up the integral output voltage 121 of the integrator circuit 110 from the output terminal 109 in the stable state to be measured can facilitate the measurement of the voltage 122 at the bit transition point corresponding to the digital code 103 supplied to the input terminal. Although the triangular wave is superimposed on the integral output voltage 121 of the integrator circuit 110 in the foregoing example, a sawtooth wave can also be used, enabling the same operation. This holds true in the following embodiments.

As described above, the present embodiment 1 is configured such that the compare decision circuit 104 compares the output digital code 102 of the A/D converter 101 to be measured with the digital code 103 indicating the bit transition point provided for the measurement, and produces as the decision output the digital signal 123 with the duty factor corresponding to the difference between the two digital codes, that the switching circuits 107 and 108, which respond to the digital signal 123, connect the positive current source 105 to the integrator circuit 110 during the time period T1 in which the decision output 123 indicates that the output digital code 102 is greater than the digital code 103 representing the bit transition point in order to reduce the integral output voltage 121, and connect the negative current source 106 to the integrator circuit 110 during the time period T2 in which the decision output 123 indicates that the output digital code 102 is smaller than the digital code 103 in order to increase the integral output voltage 121, that the adder-subtracter circuit 115 superimposes the specified triangular wave or sawtooth wave on the integral output voltage 121 of the integrator circuit 110 and supplies its output to the A/D converter 101 to be measured, and that the integral output voltage 121 of the integrator circuit 110 is picked up for the measurement. Thus, the present embodiment 1 can automatically converge the integral voltage 121 output from the integrator circuit 110 to the voltage at the bit transition point by setting the digital code 103 for the measurement at the input terminal. Accordingly, it offers an advantage of being able to speed up and facilitate the measurement of the bit transition point. Incidentally, although the integrator circuit 110 uses the inverting input in the example, this is not essential. It is possible to employ an integrator circuit using the non-inverting input, in which case the sign of the current source connected to the integrator circuit must be reversed.

### EMBODIMENT 2

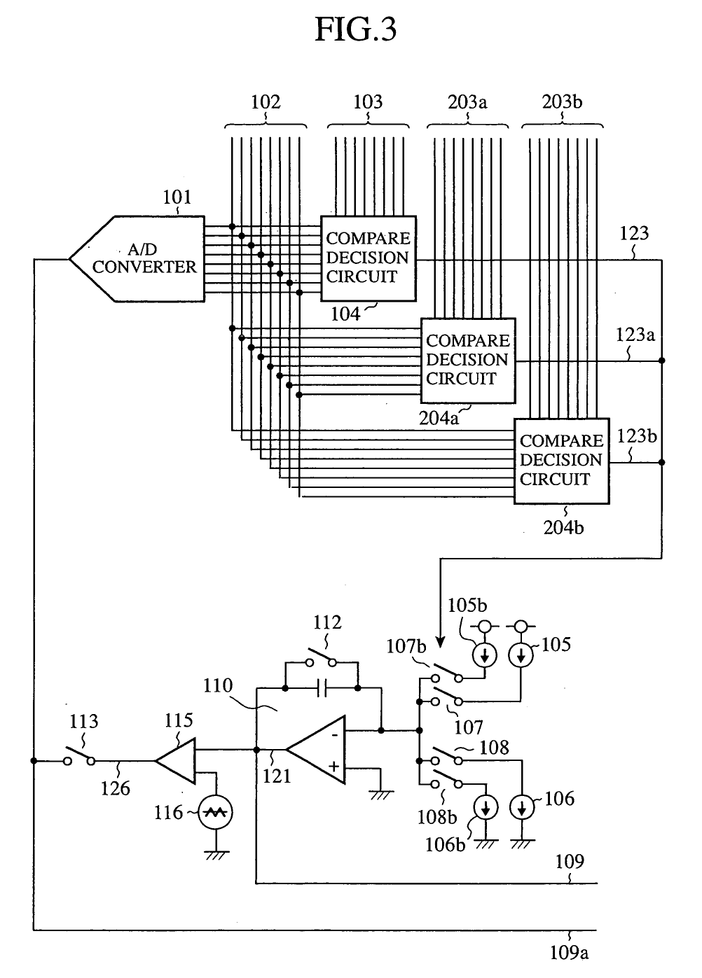

FIG. 3 is a circuit diagram showing a configuration of an embodiment 2 of the test device of the A/D converter in accordance with the present invention. In FIG. 2, the same or like portions to those of FIG. 1 are designated by the same reference numerals. The present embodiment 2 differs from the embodiment 1 in that it includes a plurality of compare decision circuits 204a and 204b in addition to the compare decision circuit 104, and a positive current source 105b and negative current source 106b besides the positive current source 105 and negative current source 106. It is assumed that the absolute values of the currents of the current sources 105b and 106b are made substantially equal.

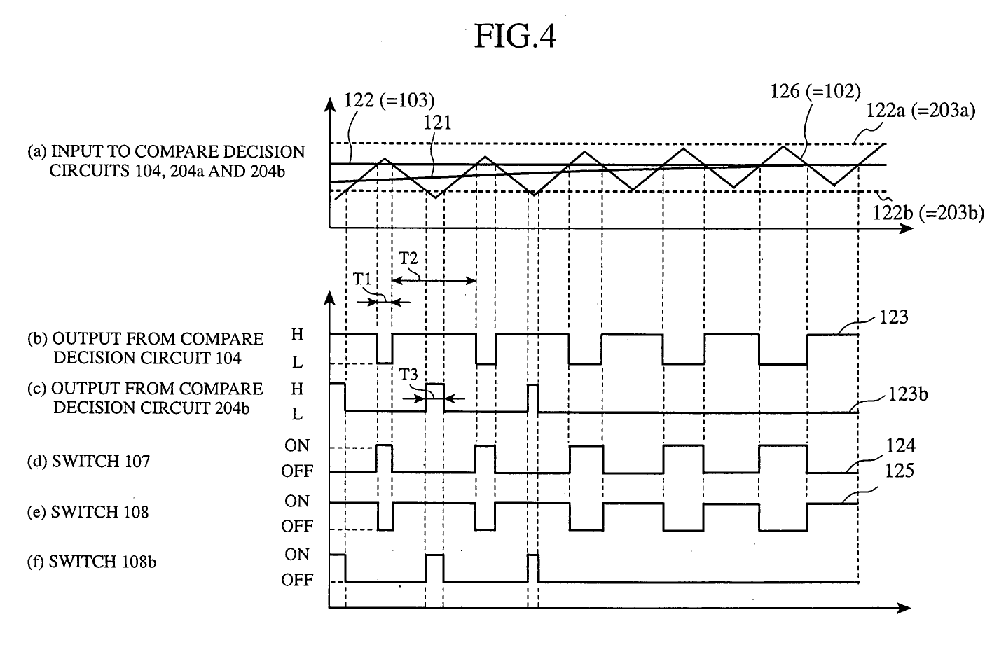

A digital code 203a fed to the input terminal of the compare decision circuit 204a takes a value greater than the value of the digital code 103 representing the bit transition point (by about 3 bits, for example), which is fed to the compare decision circuit 104. In contrast, a digital code 203b fed to the input terminal of the compare decision circuit 204b takes a value smaller than the value of the digital code 103 representing the bit transition point (by about 3 bits, for example). FIG. 4 is a time chart illustrating them. In FIG. 4, the voltage 122a, which is set higher than the voltage 122 corresponding to the bit transition point, is a voltage corresponding to the digital code 203a of the compare decision circuit 204a. In contrast, the voltage 122b, which is set lower than the voltage 122, is a voltage corresponding to the digital code 203b of the compare decision circuit 204b.

Consider the case where the output digital code 102 of the A/D converter 101 to be measured is sufficiently lower than the specified digital code 103, and is even lower than the digital code 203b. In FIG. 4, this is represented that the triangular wave of the output voltage 126 of the adder-subtracter circuit 115 is lower than the voltage 122 at the bit transition point, and is even lower than the voltage 122b corresponding to the digital code 203b. In this case, the switch 108 is closed during the time period T2 so that the negative current source 106 is connected to the integrator circuit 110 as in the embodiment 1. In addition, during a time period T3 in the time period T2, the output 123b of the compare decision circuit 204b becomes “H”, during which the switch 108b is closed and the negative current source 106b is connected to the integrator circuit 110. Thus, during the time period T3, the two negative current sources 106 and 106b are connected to the integrator circuit 110 at the same time. As a result, the integral output voltage 121 of the integrator circuit 110 increases quickly toward the voltage 122 at the bit transition point. This makes it possible to speed up the measurement of the A/D converter 101 than in the embodiment 1.

Next, consider the case where part of the triangular wave of the output voltage 126 of the adder-subtracter circuit 115 exceeds the voltage 122a (which case is not shown in FIG. 4). In this case, in response to the decision outputs 123 and 123a of the compare decision circuits 104 and 204a, time periods occur during which the switches 107 and 107b are closed. During these time periods, both the positive current sources 105 and 105b are connected to the integrator circuit 110 so that the integral output voltage 121 of the integrator circuit 110 falls at a higher rate toward the voltage 122 at the bit transition point. This can increase the measurement speed of the A/D converter 101 as compared with that of the embodiment 1.

In either case, once the output wave 126 of the adder-subtracter circuit 115 enters the range between the upper and lower set voltages 122a and 122b, the decision output 123 of the compare decision circuit 104 controls the connection of the positive current source 105 and negative current source 106 to the integrator circuit 110 in the same manner as the embodiment 1 so that the integral output voltage 121 of the integrator circuit 110 approaches the voltage 122 at the bit transition point. Thus, the control system reaches the equilibrium, and the integral output voltage 121 of the integrator circuit 110 becomes stable without fluctuations.

As described above, in addition to the embodiment 1, the present embodiment 2 is configured such that the second compare decision circuit 204a is supplied with the digital code 203a greater than the digital code 103 fed to the compare decision circuit 104 as the data representing the bit transition point, compares the digital code 203a with the output digital code 102 of the A/D converter 101 to be measured, and produces the digital signal 123a with the duty factor corresponding to the difference between the two digital codes 102 and 203a as the second decision output, that the third compare decision circuit 204b is supplied with the digital code 203b smaller than the digital code 103 representing the bit transition point, compares the digital code 203b with the output digital code 102 of the A/D converter 101 to be measured, and produces the digital signal 123b with the duty factor corresponding to the difference between the two digital codes 102 and 203b as the third decision output, and that the switching circuits 107, 107b, 108 and 108b connect the second positive current source 105b to the integrator circuit 110 during the time periods in which the second decision output 123a indicates that the output digital code 102 of the A/D converter 101 is greater than the upper digital code 203a, and connect the second negative current source 106b to the integrator circuit 110 during the time periods in which the third decision output 123b indicates that the output digital code 102 of the A/D converter 101 is smaller than the lower digital code 203b. As a result, the present embodiment 2 offers an advantage of being able to achieve better response characteristics than the embodiment 1.

### EMBODIMENT 3

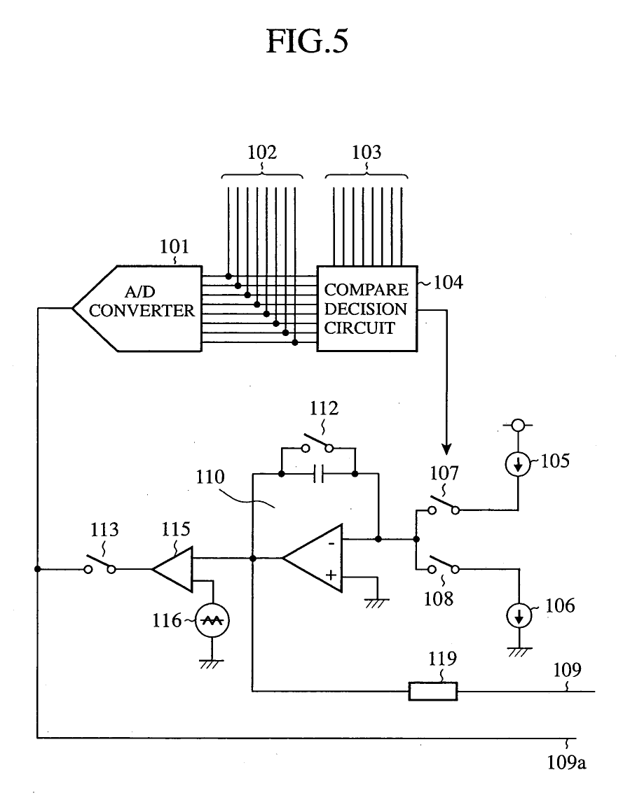

FIG. 5 is a circuit diagram showing a configuration of an embodiment 3 of the test device in accordance with the present invention. The present embodiment 3 differs from the embodiment 1 as shown in FIG. 1 in that it has a filter circuit 119 connected between the integrator circuit and the measurement output circuit, for outputting the integral output voltage 121 for measurement. The filter circuit 119 smoothes the integral value and absorbs the switching noise of the switches 107 and 108. Consequently, the present embodiment 3 can produce highly accurate measurement result.

### EMBODIMENT 4

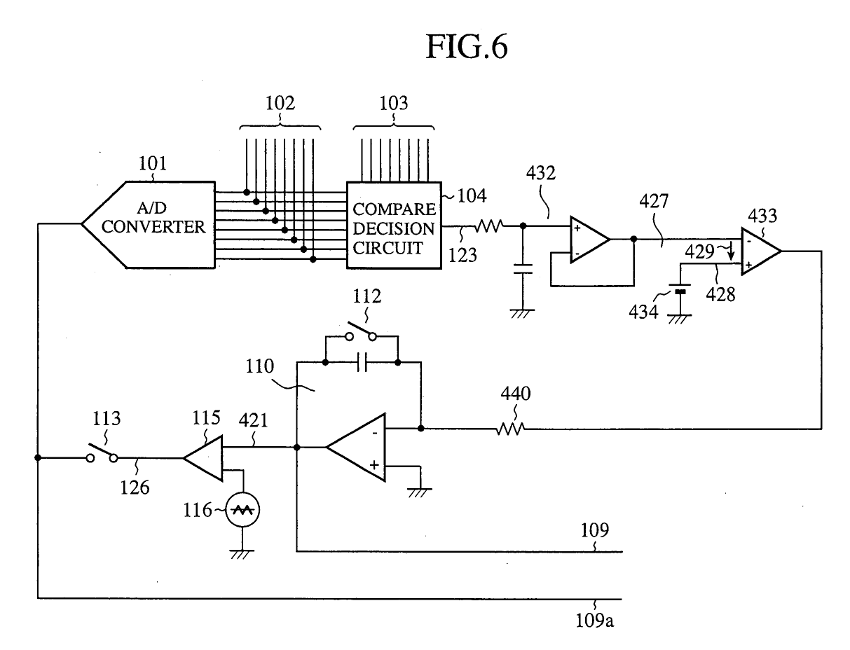

FIG. 6 is a circuit diagram showing a configuration of an embodiment 4 of the test device of the A/D converter in accordance with the present invention. The configuration of FIG. 6 differs from that of FIG. 1 in that it includes an integrator circuit 432, a reference voltage source 434 and a voltage-difference-to-current converter 433 instead of the switches 107 and 108 and the positive current source 105 and negative current source 106. In other words, the present embodiment 4 is arranged to achieve the same effects as those of the foregoing embodiments 1-3 without using the current sources and switching circuits.

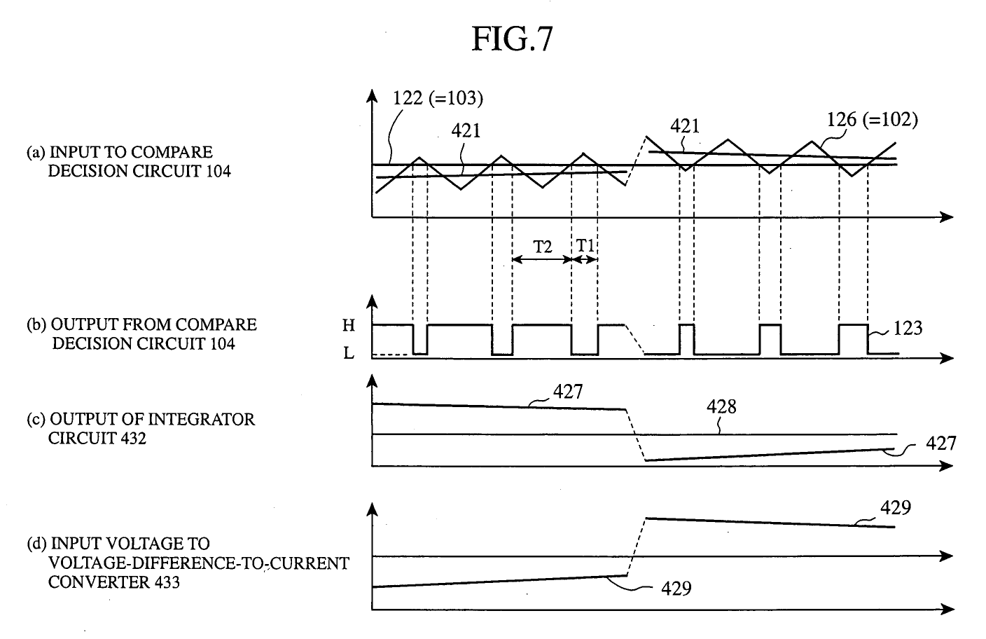

Referring to the time chart of FIG. 7, the operation of the present embodiment 4 will be described. Receiving the digital signal 123 produced as the decision output of the compare decision circuit 104, the integrator circuit 432 integrates the decision output 123. The voltage-difference-to-current converter 433 converts the difference voltage 429 between the integral output voltage 427 of the integrator circuit 432 and the reference voltage 428 of the reference voltage source 434 into a current value. The output current of the voltage-difference-to-current converter 433 is supplied to the integrator circuit 110 via a resistor 440.

As illustrated in FIG. 7, when the integral output voltage 421 of the integrator circuit 110 is smaller than the voltage 122 at the bit transition point, the duty factor of the decision output 123 of the compare decision circuit 104 is given by ½<T2/(T1+T2) because of the triangular wave superimposed. This means that T1<T2 holds, and the integral output voltage 427 of the integrator circuit 432 in this state is higher than the reference voltage value 428 of the reference voltage source 434. The voltage-difference-to-current converter 433 converts the negative voltage 429, which is obtained by subtracting the integral output voltage 427 of the integrator circuit 432 from the reference voltage 428, into the current. The resultant negative current is supplied to the integrator circuit 110. Thus, the integral output voltage 421 of the integrator circuit 110 increases so that it approaches the voltage 122 at the bit transition point.

In contrast, when the integral output voltage 421 of the integrator circuit 110 is greater than the voltage 122 at the bit transition point, the duty factor of the decision output 123 of the compare decision circuit 104 is given by ½>T2/(T1+T2). This means that T1>T2 holds, and the integral output voltage 427 of the integrator circuit 432 in this state is lower than the reference voltage value 428. The voltage-difference-to-current converter 433 converts the positive voltage 429, which is obtained by subtracting the integral output voltage 427 of the integrator circuit 432 from the reference voltage 428, into the current. The resultant positive current is supplied to the integrator circuit 110. Thus, the integral output voltage 421 of the integrator circuit 110 reduces so that it approaches the voltage 122 at the bit transition point.

In either operations, once T1=T2 is achieved, the current supplied from the voltage-difference-to-current converter 433 to the integrator circuit 110 becomes zero. Thus, the integral output voltage 421 of the integrator circuit 110 is fixed, and the equilibrium is implemented. Consequently, the bit transition point corresponding to the digital code 103 supplied to the compare decision circuit 104 can be measured by measuring the integral output voltage 421 of the integrator circuit 110 at the output terminal 109.

As described above, the present embodiment 4 is configured such that the compare decision circuit 104 compares the output digital code 102 of the A/D converter 101 to be measured with the digital code 103 representing the bit transition point for the measurement, and produces as the decision output the digital signal 123 with the duty factor corresponding to the difference between the two digital codes, that the first integrator circuit 432 integrates the digital signal 123 produced as the decision output, and the voltage-difference-to-current converter 433 converts the difference between the reference voltage 428 and the integral output voltage 427 of the first integrator circuit 432 into the current with the magnitude and direction of the difference voltage, that the second integrator circuit 110 integrates the current to generate the integral output voltage 421 that will equalize the two digital codes 102 and 103, and the adder-subtracter circuit 115 superimposes the specified triangular wave signal or sawtooth wave signal on the integral output voltage 421 of the second integrator circuit 110 to output it as the input voltage to the A/D converter 101 to be measured, and that the integral output voltage 421 of the second integrator circuit 110 is produced as the voltage to be measured. Thus, the present embodiment 4 offers an advantage of being able to speed up and facilitate the measurement of the bit transition point by superimposing the triangular wave on the voltage to be supplied to the A/D converter 101 during the measurement, by producing the digital signal 123 as the decision output by comparing the digital code 102 output from the A/D converter with the digital code 103 set for the measurement to obtain the bit transition point of the A/D converter 101, and by carrying out the control for obtaining the bit transition point of the A/D converter in response to the duty factor of the digital code 123.

What is claimed is:

1. A test device of an A/D converter comprising:
a first compare decision circuit for comparing an output digital code output from an A/D converter to be measured with a digital code representing a bit transition point supplied for measurement, and for generating as a first decision output a digital signal with a duty factor corresponding to a difference between the two digital codes compared;
a current supply circuit for supplying a current in response to the duty factor of the first decision output;
a first integrator circuit for integrating the current supplied from said current supply circuit to generate an integral output voltage with such a sign that the two digital codes compared by said first compare decision circuit are equalized;
an adder-subtracter circuit for superimposing one of a triangular wave signal and sawtooth wave signal on the integral output voltage of said first integrator circuit to be output as an input voltage to said A/D converter to be measured; and
a measurement output terminal for outputting the integral output voltage of said first integrator circuit for measurement.

2. A test device of an A/D converter according to claim 1, wherein said current supply circuit comprises:
a first positive current source;
a first negative current source, an absolute value of said first negative current source being set substantially equal to a current value of said first positive current source; and
a switching circuit for connecting a first one of said first positive current source and said first negative current source to said integrator circuit during a time period in which the decision output indicates that the output digital code of the A/D converter to be measured is greater than the digital code representing the bit transition point, to reduce the integral output voltage, and for connecting a second one of said first positive current source and said first negative current source to said integrator circuit during a time period in which the decision output indicates that the output digital code of the A/D converter to be measured is smaller than the digital code representing the bit transition point, to increase the integral output voltage.

3. The test device of the A/D converter according to claim 2, further comprising:
a second compare decision circuit for comparing the output digital code output from said A/D converter to be measured with an upper digital code which is greater than the digital code representing the bit transition point, and for generating as a second decision output a digital signal with a duty factor corresponding to a difference between the two digital codes compared; and
a third compare decision circuit for comparing the output digital code output from said A/D converter to be measured with a lower digital code which is smaller than the digital code representing the bit transition point, and for generating as a third decision output a digital signal with a duty factor corresponding to a difference between the two digital codes compared, wherein
said current supply circuit further comprising:
a second positive current source; and
a second negative current source, an absolute value of said second negative current source being set substantially equal to a current value of said second positive current source, and wherein
said switching circuit of said current supply circuit connects to said integrator circuit one of said second positive current source and said second negative current source, which has a same current direction as one of said first positive current source and first negative current source, which is connected to said integrator circuit, such that the integral output voltage is reduced during a time period in which the second decision output indicates that the digital code output from said A/D converter is greater than the upper digital code, and that the integral output voltage is increased during a time period in which the third decision output indicates that the digital code output from said A/D converter is smaller than the lower digital code.

4. The test device of the A/D converter according to claim 2, further comprising a filter circuit connected between said integrator circuit and said measurement output terminal, for outputting the integral output voltage of the integrator circuit for the measurement.

5. The test device of an A/D converter according to claim 1, wherein said current supply circuit comprises:
a second integrator circuit for integrating the digital signal as the first decision output; and
a voltage-difference-to-current converter for converting a difference voltage between a reference voltage and an integral output voltage of said second integrator circuit into a current corresponding to the difference voltage.
